(19) United States
(12) Patent Application Publication
(10) Pub. No.: US 2010/0315784 A1
(43) Pub. Date: Dec. 16, 2010

(54) FASTENING CLAMP

(76) Inventor: Thomas Schlittmeier, Altdorf (DE)

Correspondence Address: MICHAEL J. STRIKER, 103 EAST NECK ROAD, HUNTINGTON, NY, 11743, US

(21) Appl. No.: 12/739,180

(22) PCT Filed: Sep. 11, 2008
(86) PCT No.: PCT/EP08/62090

§ 371 Date: Sep. 2, 2010

(30) Foreign Application Priority Data
Oct. 25, 2007 (DE) 102007050985.7

(51) Int. Cl. H05K 7/20

(52) U.S. Cl. 361/709

(57) ABSTRACT

The invention relates to a fixing element (10), in particular in the form of a fixing clamp, for fixing an electronic component (12, 14) to a surface (18) of a cooling body (16). The fixing element (10) has a first free end (44) and a second free end (46), wherein the first free end (44) is formed by a first straight section (28). At least one projection (30) is provided on the first straight section (28), which can be detachably clipped into a recess (22, 24) of the cooling body (16) beneath an overhang (58).

### BACKGROUND INFORMATION

The present invention relates to a fastening element for fastening an electronic component to a surface of a heat sink.

G 85 16 915.3 relates to a heat sink for cooling a semiconductor component. The heat sink includes a flat cooling-contact area for cooling a semiconductor component which may be pressed against the cooling-contact area using a spring element. The heat sink is fastened to the flat assembly on which the semiconductor component is mounted. The heat sink is situated and designed in a manner such that the cooling-contact area extends perpendicularly to the plane of the flat assembly, and a plurality of cooling ribs that are situated vertically one on top of the other is provided on the side facing away from the cooling-contact area. A leaf spring that is situated at a vertical distance away from the cooling-contact area is clamped to the upper end of the heat sink, and its free end is angled toward the cooling-contact surface approximately at a right angle and bears resiliently in the central region of the semiconductor component located between them.

DE 20 2005 020 760 U1 relates to a system that includes a heat sink and an electronic component located inside of it. According to this solution, the system includes a heat sink, an electronic component located on it, and a clamping spring for pressing the component against the heat sink. The clamping spring is designed as an additional cooling element. The clamping spring is made of a material that has a higher thermal conductivity than that of the electronic component, and that is higher, in particular, than that of steel, in particular spring steel.

U.S. Pat. No. 5,068,764 relates to a fastening system for an electronic component. According to this solution, an electronic component is held in tight-fitting contact with a heat sink. An element that is substantially flat and elongated in design has a free end and is designed such that an electronic component that includes diametrically opposed first and second surfaces may be situated opposite the substantially flat component. A support element extends from the other end of a base element at an angle of less than 90° relative to the plane of the surface of the base element. A retaining element is provided that is a deformation in the carrier element and extends away from the carrier element into a position that is on the other side of the plane of the second flat surface of the electronic component and is designed such that it may be retained and accommodated inside an opening in the surface. The surface is a surface of a heat sink that is substantially parallel to and bears against the second surface of the electronic component.

### ADVANTAGES OF THE INVENTION

The object of the present invention is to optimize the fastening between an electronic component and a heat sink connected thereto.

According to the present invention it is provided that the fastening element, which connects a heat sink to an electronic component to be cooled and is designed as a clamp in particular, is optimized in a manner such that an even bending load is given along the entire length of the component.

A larger elastic bending range may be realized due to the design of the fastening element, which is designed as a clamp in particular, having an even bending load along the entire length of the component. By designing the fastening element—which is designed as a clamp in particular—to have a larger elastic bending range, it is possible to use the same fastening element to fasten components that have different heights. This may be attained using the same component which has very compact outer dimensions.

To fix a free end of the fastening element, which is designed as a clamp in particular, a recess is formed in the heat sink, which has a substantially 90° orientation to its surfaces, e.g., a groove having a substantially rectangular cross section. The groove is preferably milled in a position that is oriented 90° relative to the surface of the heat sink, or it is formed in the heat sink using another machining manufacturing method. The material of the heat sink is preferably a metallic material having excellent properties of thermal conduction, such as aluminium.

The costs to manufacture the recess are minimized due to the position of the at least one recess, which is preferably designed as a groove, substantially perpendicular to a first flat surface of the heat sink. In addition, the fastening element, which is designed as a clamp in particular, may be released without the use of tools simply by applying force perpendicularly to the snapping-in direction. Advantageously, to this end, the groove is formed in the material of the heat sink in a manner such that it has a substantially rectangular cross section. The recess, which is designed as a groove in particular, may include an overhang, in particular a projection, below which a free end of the fastening element, which is designed as a clamp in particular, snaps into place. To this end, the free end of the fastening element, which is designed as a clamp in particular, includes a projection that has been impressed or punched, and that bears against and is snapped into the opening of the recess in the material of the heat sink in the state in which the free end of the fastening element, which is designed as a clamp in particular, is snapped into place underneath the projection. To simplify removal, a lateral boundary wall—not the groove base—which is opposite the projection formed in the solid material of the heat sink may be manufactured at a slant, and may extend diagonally, in particular, in the material of the heat sink. Via the diagonally extending boundary wall of the recess, which is designed as a groove in particular, one side of the free end of the fastening element, which is designed as a clamp in particular, on the side of the free end of the fastening element that is opposite the impressed or punched projections always bears against a boundary wall of the recess, which is designed as a groove in particular, and which extends diagonally in the heat sink material. An introduction of force onto the free end of the fastening element, which is designed as a clamp in particular, the free end being snapped into the recess, which is designed as a groove in particular, perpendicularly to the snapping-in direction is sufficient to move the projections—which are impressed or punched into the free end of the fastening element, which is designed as a clamp in particular, and which are located underneath the projection in the heat sink—away, and therefore the free end emerges from the recess, which is designed as a groove in particular, opposite the installation direction and in the direction of removal—that is, in the vertical direction, upward—along the sliding surface.

Via the solution provided according to the present invention, smaller dimensions of the recess, which is designed as a groove in particular and into which the fastening element snaps into place, may be realized on the fastening element, which is designed as a clamp in particular. If the recess, which is designed as a groove in particular, may be designed to have smaller dimensions, material costs are reduced due to the solid material of the heat sink, which must be abraded, and, in particular, removed using machining methods. According to the solution that is provided, there are no overhanging geometries on the contact surface between the electronic component to be cooled and the heat sink. As a result, it is possible to realize free placement of the components, and a plurality of recesses, which are designed as grooves in particular, may be formed in a flat surface of the heat sink. In particular, the profile of the heat sink is easier to mould due to the straight recess, which is designed as a groove in particular. Furthermore, it becomes possible to easily remove the fastening element, which is preferably designed as a clamp, by hand and without the use of tools. To release the fastening element, which is designed as a clamp in particular, it is sufficient to simply introduce force perpendicularly to the installation direction of the free end of the clamp in the recess in order to release the impressed or punched projections that are formed on the free end of the fastening element, which is designed as a clamp in particular, from underneath the undercut at the inlet opening of the recess. Furthermore, the fastening element, which is designed as a clamp in particular and is provided according to the present invention, may be reused without limitation.

In an advantageous embodiment of the idea on which the present invention is based, the fastening element, which is designed as a clamp in particular, is manufactured out of a flat material. The recess, which is designed as a groove in particular, is formed in the heat-sink material, e.g., aluminum, during extrusion. The fastening element, which is designed as a clamp in particular, preferably includes two main components, that is, a straight piece that includes bulges that extend in the manner of hooks, against which a curved section (bend) abuts, and a further straight piece that includes a tapered run-out. The recess, which is designed as a groove in particular, in the solid material of the heat sink includes a diagonally oriented sliding surface for a free end of the fastening element, which is designed as a clamp in particular, and a projection that is opposite thereto and forms an undercut.

### BRIEF DESCRIPTION OF THE DRAWINGS

The present invention will be described in greater detail below with reference to the drawings.

In the drawings:

FIG. 1 shows the fastening element, which is designed as a clamp in particular and is provided according to the present invention, in the uninstalled state,

FIG. 2 shows the fastening element, which is designed as a clamp in particular and is provided according to the present invention, in the installed state, and

FIG. 3 shows an enlarged view of the free end of the fastening element, which is designed as a clamp in particular, which has been snapped into place in a recess in a heat sink.

### EMBODIMENTS

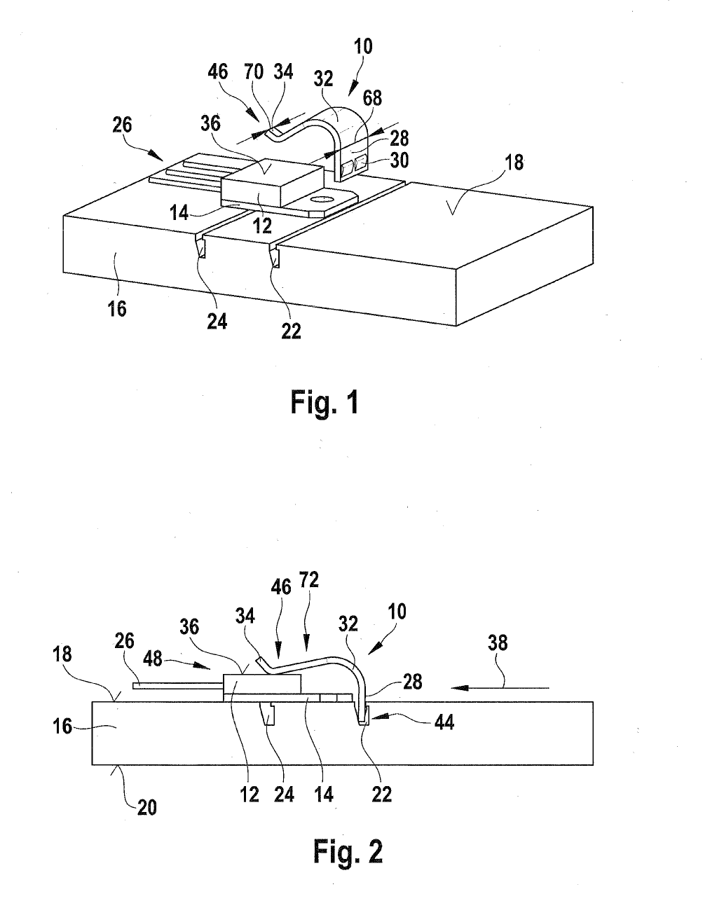

The illustration presented in FIG. 1 shows the perspective view of a fastening element that is provided according to the present invention, an electronic component to be fixed in position, and a heat sink.

FIG. 1 shows a fastening element 10 that is preferably designed in the form of a clamp. Using fastening element 10, an electronic component 12, which may include a base plate 14 or the like, if necessary, is fastened onto a first flat surface 18 of a heat sink 16. In addition to first flat surface 18, heat sink 16 includes a second flat surface 20 or ribs, or the like. Heat sink 16 is preferably manufactured out of a material which has excellent properties of thermal conduction, such as aluminum, and which is also very easy to machine.

As shown in the perspective view in FIG. 1, a first recess 22 and a second recess 24 are formed in first flat surface 18 of heat sink 16. First recess 22, second recess 24, and, if necessary, additional recesses for fixing further electronic components 12—which are designed to include a base plate 14, or not—are formed, e.g., via material-removing manufacture, e.g., in the form of grooves in the material of heat sink 16, or they are created via extrusion. Electronic component 12 includes electrical contacting 26 which may be designed, e.g., as flexfoil, a cable strand or—as shown in FIG. 1—as single-cable contacting.

As likewise shown in FIG. 1, fastening element 10, which is designed as a clamp in particular, includes a first, straight section 28 that forms a first free end 44 of fastening element 10. Bulges or projections 30—which are adjacent to one another in this embodiment—are formed in this first, straight section 28, as shown in FIG. 1. In the case of a fastening element 10 which is manufactured out of a metallic material, the at least one projection or the at least one bulge 30 may be impressed or stamped out. A bend 32 adjoins first, straight section 28 of fastening element 10, which is preferably designed as a clamp. Bend 32, in turn, is adjoined by a run-out 34, the width of which tapers, and which is a second free end 46 of fastening element 10. Using this, electronic component 12—as shown in FIG. 1—is contacted at a contact surface 36 and, if necessary, is pressed against first flat surface 18 of heat sink 16, with base plate 14 between the two. In the illustration shown in FIG. 1, a first width of fastening element 10, which is preferably designed as a clamp, is labelled using reference numeral 68 in the region of first free end 44, while a second width 70 is present on tapered run-out 34 of fastening element 10, which is preferably designed as a clamp.

FIG. 2 shows a side view of the electronic component which is pressed against the heat sink via the fastening element.

As shown in FIG. 2, first recess 22 and second recess 24 extend through heat sink 16, through the plane of the drawing. First recess 22 and second recess 24 have a substantially rectangular cross section. As shown in the illustration in FIG. 2, fastening element 10, which is preferably designed as a clamp, is inserted via a first free end 44 and the at least one projection 28 formed there into first recess 22. In contrast, second recess 24 is covered by base plate 14 of electronic component 12 which is pressed against first flat surface 18 of heat sink 16, in position 48. Electronic component 12 is held in place via a clamping force 72.

Furthermore, FIG. 2 shows that second free end 46, which includes run-out 34 that is tapered via its second width 70, is pressed against contact surface 36, i.e., the top side of electronic component 12. Due to the elasticity of fastening element 10, which is preferably designed as a clamp, electronic component 12, including base plate 14, is pressed against first flat surface 18 of heat sink 16. As likewise shown in FIG. 2, first free end 44 of fastening element 10, which is designed as a clamp, is simply inserted into first recess 22 of heat sink 16. Via the shaping of fastening element 10 to include a first, straight region 28, adjoining bend 32, and tapered run-out 34, an even bending load across the entire length of the component is attained. This makes it possible to attain a larger bending region, thereby making it possible to fasten electronic components on heat sink 16 that are taller than electronic component 12, including base plate 14, that is shown in FIGS. 1 and 2. As likewise shown in the side view according to FIG. 2, first recess 22 and second recess 24 extend substantially perpendicularly to first flat surface 18, which favorably influences the manufacturing costs of first and second recesses 22, 24, respectively, and of any further recesses that may become necessary.

First free end 44 of fastening element 10, which is preferably designed as a clamp, is simply inserted into first recess 22, in the vertical direction downward, and it snaps into place therein, without the aid of an installation or fixing element.

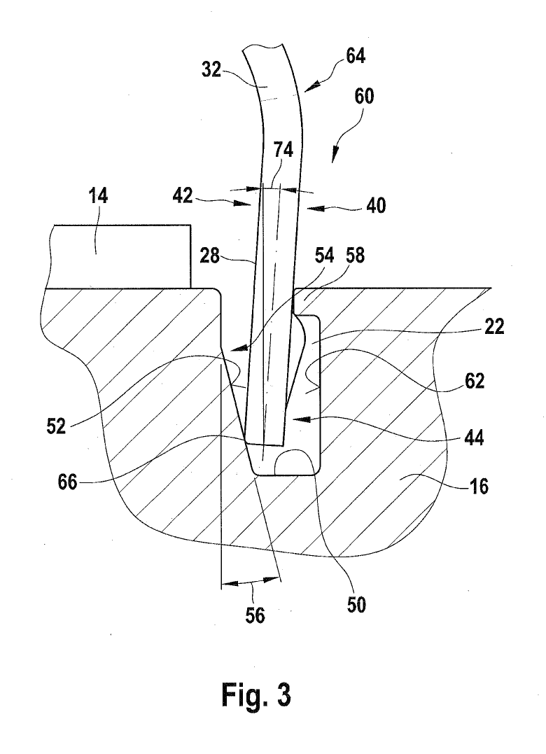

FIG. 3 shows an enlarged section of the first free end of the fastening element, which is preferably designed as a clamp, in the state in which it is snapped into position in the recess of the heat sink.

FIG. 3 shows that first end 44 of first, straight section 28 of fastening element 10, which is preferably designed as a clamp, is inserted into first recess 22. First recess 22 in heat sink 16 includes a vertical surface 62, a base 50, and a sliding surface 52. Sliding surface 52, which bounds first recess 22 and second recess 24 (not depicted), has an inclination 54. A pitch angle 56 that forms inclination 54 of sliding surface 52 is only a few angular degrees. An overhang 58 is formed above vertical surface 62 of first recess 22 and of second recess 24—which is not depicted in FIG. 3—in the material of heat sink 16. Overhang 58 is used as a lock-in projection for the at least one bulge 28 that is formed on first free end 44 of first, straight section 28. In the state of fastening element 10—which is designed as a clamp in particular—which is shown in FIG. 3, in which it is snapped into place in first recess 22, first free end 44 bears against sliding surface 52 along a contact line 66. If first free end 44 is acted upon on a first side 40 using a force that is directed in force direction 38, then, due to the deformation of first, straight section 28, the at least one bulge 30 or the at least one projection 30 is released from overhang 58, and first free end 44 may be removed from first recess 22.

When first free end 28 is inserted into first recess 22, its end face moves along a contact line 66, along sliding surface 52 and in the direction of base 50 of first recess 22. This continues until the at least one bulge 30 or the at least one projection 30 snaps into position below overhang 58 of first recess 22. An inclination angle, about which first free end 44 in first recess 22 is tilted relative to the vertical (90°), is labelled with reference numeral 74.

Via a deformation of first, straight section 28 resulting from the application of a force in force direction 38, first, straight section 28 and, therefore, fastening element 10 which is preferably designed as a clamp, may be removed from first recess 22 without the use of tools.

Fastening element 10, which is preferably designed as a clamp, is characterized by small dimensions. Due to the shaping of fastening element 10, which is preferably designed as a clamp, to include a first, straight section 28, an adjoining bend 32 after an overhang 64, and tapered run-out 34 that adjoins bend 32, excellent bending properties are imparted to fastening element 10, which is preferably designed as a clamp. Using one and the same fastening element 10, which is preferably designed as a clamp, it is possible to fasten electronic components 12 that have different heights, and which were designed to include a base plate 14, or not, onto first flat surface 18 of heat sink 16 without the use of tools. There are no overhanging geometries on the contact surface, i.e., on first flat surface 18 between heat sink 16 and electronic component 12 to be fixed thereto, or base plate 14. It is therefore possible to place electronic component 10 anywhere on first flat surface 18. Furthermore, any number of recesses 22 may be designed, one next to the other, in first flat surface 18 of heat sink 16. Due to the substantially straight recesses 22, which are designed as rectangular grooves in particular, the heat-sink profile is easier to manufacture. If recesses 22, 24 extend in the heat-sink profile at a 90° angle relative to the surface of the heat-sink profile, manufacture of the same is made considerably simpler.

As mentioned previously in conjunction with FIGS. 2 and 3, the fastening element, which is preferably designed as a clamp, may be easily removed, without the use of tools, using a force that is directed in force direction 38 and acts on first side 40. A second side is labelled using reference numeral 42. Via the action of force in force direction 38, first, straight section 28 is deformed in a manner such that the at least one projection 30 or the at least one bulge 30 are released from overhang 58, thereby making it possible to easily remove fastening element 10, which is preferably designed as a clamp, in the upward direction. Fastening element 10, which is preferably designed as a clamp, and which is provided according to the present invention, is furthermore characterized by the fact that it may be reused any number of times.

Due to the shaping of the fastening element, which is preferably designed as a clamp, in particular in tapered region 34 which contacts contact surface 36 of electronic component 12 to be fixed in position, a defined clamping force may be applied. Fastening element 10, which is preferably designed as a clamp, is also very easy to manufacture, as a punched part, out of metallic material. Depending on how first width 68 on first free end 44 or second width 70 on second free end 46 are selected, electronic components 12 having different widths—and which were designed to include a base plate 14, or not—may be fixed in position on first flat surface 18 of heat sink 14. It is possible to fix a larger, in particular wider, electronic component 12—which is designed to include base plate 14, or not—using a plurality of fastening elements 10, which are preferably designed as clamps, on first flat surface 18 of heat sink 16 without the use of tools.

If first recess 22 or second recess 24 or a larger number of recesses are formed to be continuous in first flat surface 18 of heat sink 16, then approximately entire first flat surface 18 of heat sink 16 may be used to dissipate heat from electronic components, e.g., power elements or the like, thereby making it possible to attain a high level of materials utilization.

What is claimed is:

1. A fastening element (10), which is designed as a clamp in particular, for fastening an electronic component (12, 14) to a surface (18) of a heat sink (16), comprising a first free end (44) and a second free end (46), the first free end (44) being formed by a first, straight section (28),
wherein
at least one projection (30) is formed on the first, straight section (28), which is detachably snapped into a recess (22, 24) of the heat sink (16) underneath an overhang (58).

2. The fastening element (10) as recited in claim 1,
wherein
the fastening element (10) has a bend (32) that adjoins the first, straight section (28), and a tapered section (34) that adjoins the bend (32).

3. The fastening element (10) as recited in claim 1,
wherein
a first width (68) of the first, straight section (28) is greater than a second width (70) of the tapered section (34) of the fastening element (10).

4. The fastening element (10) as recited in claim 1,
wherein
the first, straight section (28) is deformable via a force (38) that is oriented perpendicularly thereto in such a manner that a snap-in connection (30, 58) in a recess (22, 24) is released.

5. The fastening element (10) as recited in claim 1,
wherein
the at least one projection (30) is formed on the side (40) of the first, straight section (28) onto which the force (38) acts in order to release the snap-in connection (30, 58).

6. The fastening element (10) as recited in claim 1,
wherein
the fastening element (10) is made of a metallic material.

7. The fastening element (10) as recited in claim 1,
wherein
the at least one projection (30) is formed on a first free end (44) of the fastening element (10) as a punching or indentation.

8. The fastening element (10) as recited in claim 1,
wherein
the first free end (44) is snapped into a recess (22, 24) in the heat sink (16), which has a substantially rectangular cross section, via the first, straight section (28) and without the use of tools.

9. The fastening element (10) as recited in claim 1,
wherein
the recess (22, 24) is limited by a vertical surface (62), above which the overhang (58) extends, and by a diagonally extending sliding surface (52).

10. A system composed of a fastening element (10), a heat sink (16) that includes a first flat surface (18), and an electronic component (12, 14) to be cooled, characterized by a fastening element (10) as recited in claim 1.

11. The system as recited in the preamble of claim 10, comprising a fastening element (10), a heat sink (16) that includes a first flat surface (18), and an electronic component (12, 14) to be cooled,
wherein
the fastening element (10) bears via a tapered run-out (34) against a contact surface (36) of the electronic component (12, 14) to be mounted on the first flat surface (18) of the heat sink (16), and is fixed, without the use of tools and via a first free end (44), in a recess (22, 24) in the material of the heat sink (16).

12. The system as recited in claim 10,
wherein
at least one recess (22, 24) that includes a sliding surface (52) and an overhang (58) extends in the heat sink (16), the overhang (58) and the sliding surface (52) extending along the length of the at least one recess (22, 24) in the material of the heat sink (16).
